(19) United States
(12) Patent Application Publication
(10) Pub. No.: US 2008/0283999 A1
(43) Pub. Date: Nov. 20, 2008

(54) Chip Package with Pin Stabilization Layer

(76) Inventors: Eric Tosaya, Fremont, CA (US); Srinivasan Parthasarathy, Palo Alto, CA (US)

Correspondence Address: TIMOTHY M HONEYCUTT ATTORNEY AT LAW, P O BOX 1577, CYPRESS, TX, 77410, US

(21) Appl. No.: 11/750,479

(22) Filed: May 18, 2007

(51) Int. Cl. H01L 23/24; B23P 19/00; H01L 21/00

(52) U.S. Cl. 257/697; 29/755; 438/106; 257/E21.001; 257/E23.14

(57) ABSTRACT

Various methods and apparatus for semiconductor packing are disclosed. In one aspect, a method of manufacturing is provided that includes coupling first ends of plural conductor pins to a first surface of a semiconductor chip package substrate. A layer is formed on the first surface that engages and resists lateral movement of the conductor pins while leaving second ends of the conductor pins exposed.

### BACKGROUND OF THE INVENTION

1. Field of the Invention

This invention relates generally to semiconductor processing, and more particularly to methods and apparatus for mounting conductor pins to semiconductor chip packages.

2. Description of the Related Art

Many current integrated circuits are formed as multiple die on a common silicon wafer. After the basic process steps to form the circuits on the die are complete, the individual die are cut from the wafer. The cut die are then usually mounted to structures, such as circuit boards, or packaged in some form of enclosure.

One frequently-used package consists of a substrate upon which a die is mounted. The upper surface of the substrate includes electrical interconnects. The die is manufactured with a plurality of bond pads. A collection of solder bumps are provided between the bond pads of the die and substrate interconnects to establish ohmic contact. An underfill material is deposited between the die and the substrate to act as an adhesive to hold the die and provide mechanical stability and strength. The substrate interconnects include an array of solder pads that are arranged to line up with the die solder bumps. After the die is seated on the substrate, a reflow process is performed to enable the solder bumps of the die to metallurgically link to the solder pads of the substrate. After the die is mounted to the substrate, a lid is attached to the substrate to cover the die. Some conventional integrated circuits, such as microprocessors, generate sizeable quantities of heat that must be dissipated to avoid device shutdown or damage. For these devices, the lid serves as both a protective cover and a heat transfer pathway.

The lower surface of the substrate of a particular type of package is known as a “pin grid array” or “PGA” package. A PGA substrate includes a number of conductor pins that are designed to connect electrically to a socket of a printed circuit board. The pins are connected to the substrate by small globs of solder, one for each pin. The solder globs bond to small metallic pin pads in the lower surface of the substrate.

The conductor pins function mechanically as small columns. Despite their often minute size (on the order of a couple of millimeters in length), conductor pins can be subject to significant mechanical loads. For conductor pins, as with all structural columns, vertical alignment is a vital component of their ability to withstand loads, particularly compressive loads. A pin that is off vertical may fail if subjected to axial loading or mis-align with a socket receptacle and prevent proper seating of the package.

For conventional packaging, the structural integrity and degree of vertical alignment of pins is dependent on the condition of the solder globs holding the pins to the substrate. This follows from the fact that the structural support for the pins is provided by the solder. If the integrity of the solder globs is compromised, the pins may move off vertical or even detach. A difficulty with the conventional design is the reflow process to establish metallurgical bonding between the die solder bumps and the substrate interconnects. This heating process can cause an unwanted transient liquification of the solder globs holding the pins. As the pin solder globs soften, the pins can move off vertical or even detach. Future solders for die attachment may eliminate lead as a constituent and thus require even higher reflow temperatures. Higher temperatures pose greater risk of pin solder degradation.

The present invention is directed to overcoming or reducing the effects of one or more of the foregoing disadvantages.

### SUMMARY OF THE INVENTION

In accordance with one aspect of the present invention, a method of manufacturing is provided that includes coupling first ends of plural conductor pins to a first surface of a semiconductor chip package substrate. A layer is formed on the first surface that engages and resists lateral movement of the conductor pins while leaving second ends of the conductor pins exposed.

In accordance with another aspect of the present invention, a method of manufacturing is provided that includes coupling first ends of plural conductor pins to a first surface of a semiconductor chip package substrate. Plural reinforcement layers are formed on the first surface. Each of the reinforcement layers engages a corresponding conductor pin to resist lateral movement of that corresponding conductor pin while leaving a second end of that corresponding conductor pin exposed.

In accordance with another aspect of the present invention, an apparatus is provided that includes a substrate that has a first surface that includes a plurality of conductor pins coupled thereto and a second surface adapted to receive a semiconductor chip. A layer is coupled to the first surface that engages and resists lateral movement of the conductor pins while leaving second ends of the conductor pins exposed.

In accordance with another aspect of the present invention, an apparatus is provided that includes a substrate that has a first surface that includes a plurality of conductor pins coupled thereto and a second surface adapted to receive a semiconductor chip. Plural reinforcement layers are coupled to the first surface. Each of the reinforcement layers engages a corresponding conductor pin to resist lateral movement of that corresponding conductor pin while leaving a second end of that corresponding conductor pin exposed.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of an integrated circuit package;

FIG. 2 is a pictorial view like FIG. 1 but with a package lid exploded to reveal the package contents;

FIG. 3 is a sectional view of FIG. 1 taken at section 3-3;

FIG. 4 is a portion of FIG. 3 shown at higher magnification;

FIG. 5 is a sectional view like FIG. 4, but of a conventional package design;

FIG. 6 is a sectional view like FIG. 4, but of an alternate exemplary embodiment of a package;

FIG. 7 is a sectional view depicting an exemplary method of forming a reinforcement layer for a package;

FIG. 8 is a sectional view depicting an alternate exemplary method of forming a reinforcement layer for a package;

FIG. 9 is a sectional view depicting an exemplary method of forming plural reinforcement layers for a package; and

FIG. 10 is sectional view depicting an alternate exemplary method of forming plural reinforcement layers for a package.

### DETAILED DESCRIPTION OF SPECIFIC EMBODIMENTS

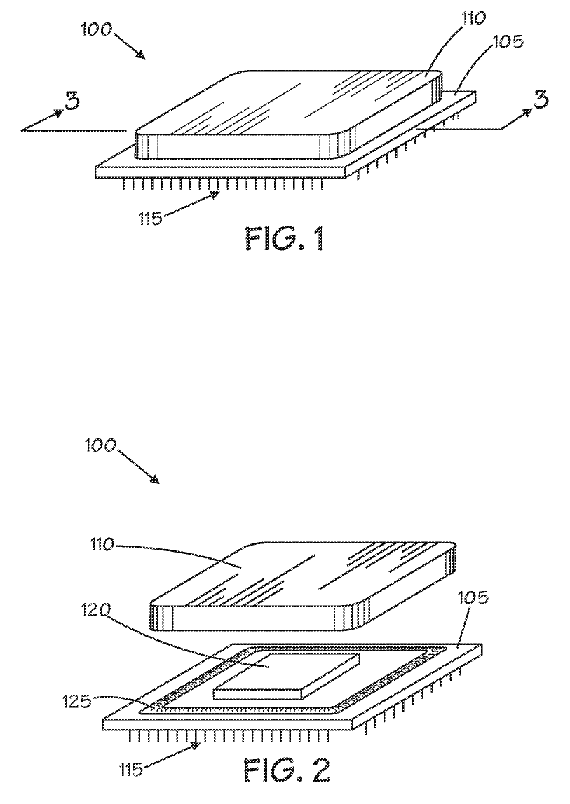

In the drawings described below, reference numerals are generally repeated where identical elements appear in more than one figure. Turning now to the drawings, and in particular to FIG. 1, therein is shown a pictorial view of an exemplary embodiment of an integrated circuit package 100 that includes a base substrate 105 and an overlying lid 110. An array of conductor pins 115 project downwardly from the base substrate 105. The lid 110 covers an integrated circuit (not visible) that is mounted on the substrate 105. Optionally, the package 100 may be lidless, partially or completely overmolded, or glob topped.

Additional detail regarding the package 100 may be understood by referring now also to FIG. 2, which is a pictorial view like FIG. 1, but with the lid 110 exploded from the base substrate 105. An integrated circuit 120, which may be a semiconductor chip or other type of device as desired is mounted on the base substrate 105. The integrated circuit 120 may be any of a myriad of different types of circuit devices used in electronics, such as, for example, microprocessors, graphics processors, application specific integrated circuits, memory devices or the like, and may be single or multi-core. An adhesive bead 125 is positioned on the base substrate 105 in order to secure the lid 110. The adhesive 125 has a general outline that tracks the shape of the perimeter of the overlying lid 110. The adhesive 125 may be a continuous bead or a series of segments as desired. The substrate 105 includes electrical interconnects that are not visible but are present to establish electrical connectivity between the array of pins 115 and various portions of the integrated circuit 120.

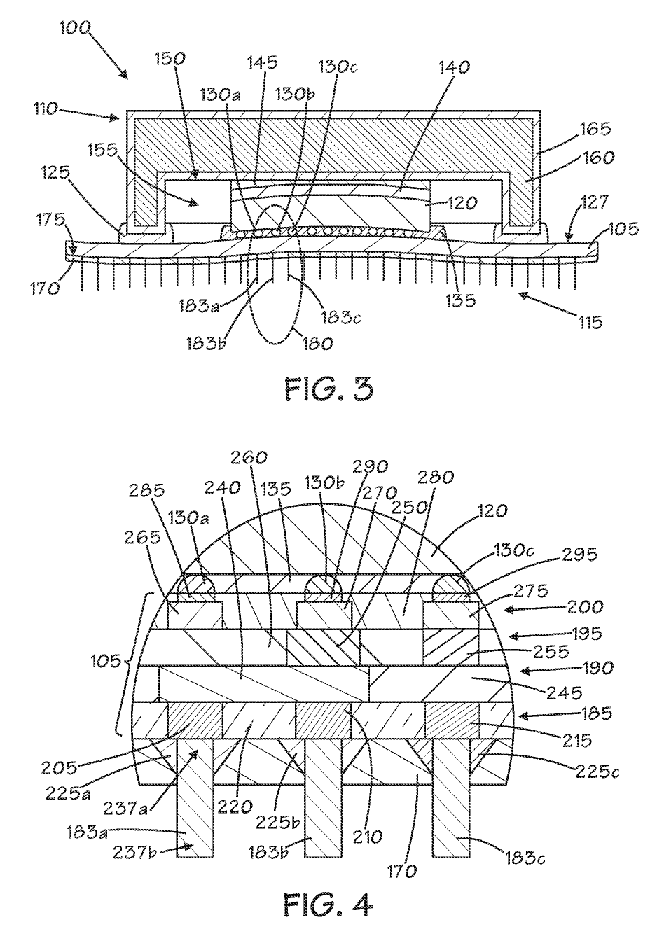

Still further details of the package 100 may be understood by referring now to FIG. 3, which is a sectional view of FIG. 2 taken at section 3-3. The integrated circuit 120 may be mounted in flip-chip fashion on an upper surface 127 of the substrate 105 and electrically connected to the array 115 of conductor pins by way of an array of solder bumps, three of which are labeled 130a, 130b and 130c respectively, and interconnect layers that are in the substrate 105 but are not visible in FIG. 3. An underfill material 135 is positioned between the integrated circuit 120 and the substrate to cushion and address issues of differing coefficients of thermal expansion for the substrate 105 and the integrated circuit 120. The integrated circuit 120 may include a backside metallization stack 140 that consists of materials that facilitate bonding between the lid 110 and a thermal interface material 145 positioned between the backside metallization stack 140 and a lower surface 150 of an interior space 155 of the lid 110. The materials suitable for the stack 140 will depend on the type of thermal interface material 145. The thermal interface material 145 is designed to bond with the lower surface 155 of the lid 110 and provide an effective conductive heat transfer pathway between the integrated circuit 120 and the lid 110. The thermal interface material 145 is advantageously composed of polymeric materials such as, for example, silicone rubber mixed with aluminum particles and zinc oxide, or metallic materials, such as indium. Optionally, compliant base materials other than silicone rubber and thermally conductive particles other than aluminum may be used. Following curing of the underfill material 135, the adhesive 125 and the thermal interface material 145, if that material requires a cure, there may be a warping of the substrate 105 that produces the somewhat recurve profile of the substrate 105 as depicted in FIG. 3.

The lid 110 may be composed of well-known plastics, ceramics or metallic materials as desired. Some exemplary materials include nickel plated copper, anodized aluminum, aluminum-silicon-carbon, aluminum nitride, boron nitride or the like. In an exemplary embodiment, the lid 110 may consist of a copper core 160 surrounded by a nickel jacket 165. Optionally, the lid 110 may be other than a bathtub configuration.

Unlike a conventional chip package in which the conductor pins are structurally supported solely by small solder cones, this illustrative embodiment includes a pin stabilization layer 170 positioned on the lower surface 175 of the substrate 105. The pin stabilization layer is designed to engage and provide extra structural support for the array 115 of conductor pins so that various types of thermal cycling processes that the substrate 105 undergoes will not result in a weakening or failure of any of the solder cones holding any of the array 115 of conductor pins. The goal is to resist lateral movement of the array 115 of pins. It should be understood that the pins in the array 115 may be oriented in virtually any orientation, including vertical. To aid in the description of further details, three pins of the array 115 of pins are separately labeled 183a, 183b and 183c respectively.

Additional detail, regarding the substrate 105 and the pin stabilization layer 170 may be understood by referring now to FIG. 4, which is a magnified view of the portion of FIG. 3 circumscribed generally by the dashed oval 180. Note that a small portion of the integrated circuit 120, the three solder bumps 130a, 130b and 130c, as well as the three labeled conductor pins 183a, 183b and 183c are visible. The description of the pins 183a, 183b and 183c will be illustrative of the other pins in the array 115 shown in FIGS. 1, 2 and 3. The conductor pins 183a, 183b and 183c themselves may have a generally cylindrical configuration, although other types of shapes such as rectangular, square, polygonal, etc. may be used as desired. The conductor pins 183a, 183b and 183c are advantageously composed of a variety of conducting materials, such as, for example copper, gold, nickel, platinum, silver alloys of these, such as Kovar, or the like. In an exemplary embodiment, the pins are composed of a copper alloy number 194 plated with nickel and gold.

The substrate 105 may actually consist of multiple layers of metallization and dielectric materials that electrically interconnect the conductor pins 183a, 183b and 183c to various portions of the integrated circuit 120. The number of individual layers is largely a matter of design discretion. In certain exemplary embodiments, the number of layers may vary from four to sixteen. For simplicity of illustration, FIG. 4 depicts four layers 185, 190, 195 and 200. The layer 185 consists of a plurality of pin pads 205, 210 and 215 surrounded laterally by a dielectric material 220. The dielectric material 220 may be, for example, epoxy resin with or without fiberglass fill. The same may be true for the remainder of the dielectric in the substrate 105. The pin pads 205, 210 and 215 may be composed of a variety of materials, such as, for example copper, nickel, gold, platinum, silver, alloys of these or the like. In an exemplary embodiment, the pin pads 205, 210 and 215 are composed of an alloy of copper, nickel and gold. This particular alloy provides advantageous wetting with solder used to secure the conductor pins 183a, 183b and 183c. The pins 183a, 183b and 183c are secured to the pin pads 205, 210 and 215 by way of respective solder cones 225, 230 and 235. The solder cones 225, 230 and 235 may be formed by a screen printing process in which solder is deposited in the locations of where the pins 115 will seat and thereafter inserting the pins 115 and performing a reflow process to wet the solder cones 225, 230 and 235 to the pins 115. Various solders may be used, such as lead-based or lead-free. In an exemplary embodiment, a lead, tin and antimony solder may be used with a composition of about 82% lead, about 10% tin and about 8% antimony.

Optionally, the substrate 105 maybe composed of ceramic and the pins 183a, 183b and 183c may be attached by braising. Ceramics are tolerant of the high temperatures necessary for braising.

The pin stabilization layer 170 is shown as a blanket layer that surrounds the pins 183a, 183b and 183c at least in the vicinity of the interconnect layer 185. The pin stabilization layer 170 may be composed of a variety of polymeric materials, such as, for example plastics, adhesives and various precured or partially cured materials. Exemplary plastics include polyimide or the like. Adhesives, such as epoxies may be used. Polyimide and epoxy are usually dispensed in liquid and then subjected to a curing stimulus of one sort or another. Precure or partial cure material may include so-called “B-stage” or “pre-preg” materials that are normally supplied in a sheet that may be thermally pressed in place. The layer 170 is advantageously, though not necessarily thicker than the solder cones 225a, 225b and 225c. However, the layer 170 should stabilize the pins 183a, 183b and 183c while still enabling the pins to establish ohmic contact with some other electrical device, such as a socket on a printed circuit board. For example, the pin 183a has an end 237a coupled to the substrate 105 and a free end 237b designed to electrically couple to another device. Accordingly, the layer 170 should engage the end 237a while leaving the free end 237b exposed. The same is true for the other pins and embodiments disclosed herein.

As noted above, the various layers 185, 190, 195 and 200 are provided to establish electrical interconnects between the pins 115 and the integrated circuit 120. The precise layout of the various metal structures in the layers 185, 190, 195 and 200 will depend upon the number of pins 115 and the complexity of the integrated circuit 120 among other things. For simplicity of illustration, the interconnect layer 190 is depicted as consisting of a conductor line 240 and a dielectric fill 245. In similar fashion, the interconnect layer 195 is depicted as consisting of conducting vias 250 and 255 surrounded laterally by a dielectric 260. The top layer 200 consists of bump pads 265, 270 and 275 again surrounded laterally by a dielectric fill 280. The vias and bump pads, etc. may be composed of a variety of materials, such as, for example, copper, nickel, gold, platinum, silver, alloys of these or the like. In an exemplary embodiment, the bump pads 265, 270 and 275 are composed of an alloy of copper, nickel and gold, and the vias 250, etc. are composed of copper. The bump pads 265, 270 and 275 are provided with prospective solder beads 285, 290 and 295 that are designed to reflow and metallurgically bond with the solder bumps 130a, 130b and 130c of the integrated circuit 120. During fabrication, the solder pads 285, 290 and 295 are deposited on the bump pads 265, 270 and 275 and the integrated circuit 120 is brought into contact with the bump pads 265, 270 and 275. A solder reflow process is next performed to establish the metallurgical bonding. Thereafter, the underfill material 135 may be deposited and cured.

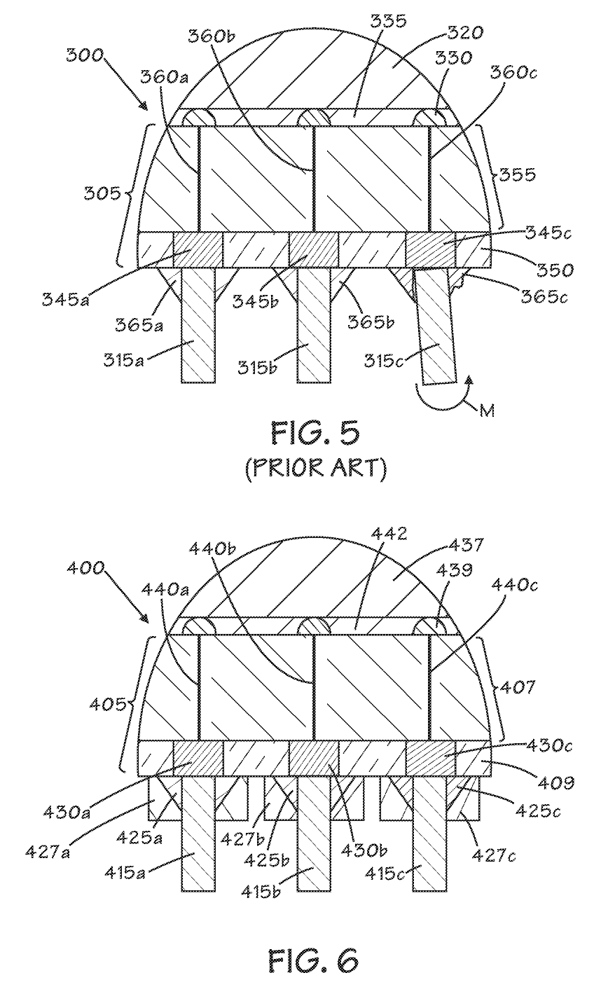

It may be useful at this point to contrast a conventional package design with the illustrative embodiment of FIG. 4. In this regard, attention is now turned to FIG. 5, which is a magnified sectional view like FIG. 4 but of a conventional package design 300. The conventional package 300 consists of a base substrate 305 with a plurality of downwardly projecting conductor pins 315 and an integrated circuit 320 mounted thereon. The integrated circuit 320 is shown flip-chip mounted with the plurality of solder bumps 330 and an underfill 335. The substrate 305 is a multi-layered structure that consists of interconnect layers. The lower most interconnect layer 340 consists of a plurality of bond pads 345a, 345b and 345c surrounded laterally by a dielectric fill 350. For simplicity of illustration, the other layers of the substrate 305 are represented as a single layer 355 and the interconnects from the pin pads 345a, 345b and 345c to the bumps 330 of the integrated circuit 320 are represented schematically by three conductor wires 355a, 355b and 355c. The pins 315a, 315b and 315c are secured to the substrate 305 solely by respective solder cones 365a, 365b and 365c. FIG. 4 is intended to illustrate a pitfall of this conventional design. It is assumed that during the various thermal cycles imposed on the substrate 305 during the cure of the underfill 330 and the reflow in order to establish metallurgical bonding for the solder bumps 330, the solder cones 365a, 365b and 365c may weaken and/or lose wetting with their respective pins 315a, 315b and 315c. If a moment such as the moment, M, is imposed on any of the pins, for example, the pin 315c, the weakened or otherwise failed solder cone 365 may cause the pin 315c to shift out of a vertical position as shown. Such a structural failure may result in a complete loss of electrical contact between the pin 315c and the pin pad 345a or the pin 315c may break off entirely depending on the severity of the stresses on the pin 315c and the level of failure of the solder cone 365c.

In the exemplary embodiment depicted in FIG. 4, the pin stabilization layer 170 is a continuous film. An alternate exemplary embodiment is depicted in FIG. 6 in which conductor pins may be provided with respective individual stabilization layers. The package 400 includes a substrate 405 that may be like the substrate 105 described elsewhere herein. For simplicity of illustration, the substrate 405 is depicted with a single upper interconnect layer 407 and a lower interconnect layer 409. However, it should be understood that the upper interconnect layer 407 may consist of multiple interconnect layers of the type depicted in FIG. 4. Pins 415a, 415b and 415c are connected to the base substrate 405 byway of respective solder cones 425a, 425b and 425c. The pins 415a, 415b and 415c are electrically connected to respective pin pads 430a, 430b and 430c that are insulated laterally by a dielectric fill 435. An integrated circuit 437 is flip-chip mounted to the substrate 405 and electrically interconnected to the pins 415a, 415b and 415c by way of bumps 439 and interconnect structures that are depicted schematically by the wires 440a, 440b and 440c. An underfill 442 cushions the integrated circuit 437. As noted above, individual pin stabilization layers 427a, 427b and 427c are provided for the respective pins 415a, 415b and 415c. The individual stabilization layers 427a, 427b and 427c are advantageously provided with a height that is at least as large as their respective solder cones 425a, 425b and 425c. The layers 427a, 427b and 427c may be composed of the same types of materials used to fabricate the pin stabilization layer 170 described above in conjunction with FIG. 4. The individual layers 427a, 427b and 427c are laterally spaced but need not be. However, lateral spacing reduces the chances that asymmetric lateral loads will be placed on the pins 415a, 415b and 415c.

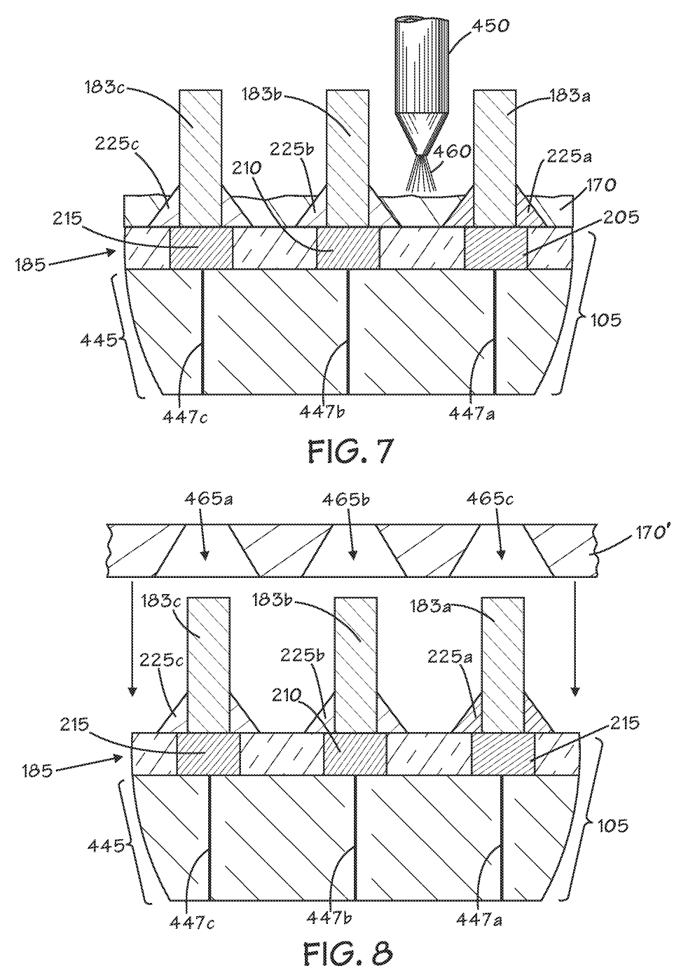

An exemplary method of fabricating a pin stabilization layer as a continuous film may be understood by referring now to FIG. 7, which is a sectional view like FIG. 4 but with the substrate 105 flipped over and shown prior to the attachment of the integrated circuit 120 thereto. Again for simplicity of illustration, the interconnect layer 185 is depicted along with the respective pin pads 205, 210 and 215, but the remainder of the substrate 105 is depicted as a single layer 445 with schematically represented interconnects 447a, 447b and 447c for simplicity of illustration. The stabilization layer 170 may be deposited by a spray nozzle 450 that disperses the liquid film 170 in and around the pins 183a, 183b and 183c and their respective solder cones 225, 230 and 235. The nozzle 450 dispenses a liquid 460 that may be a single constituent or multiple liquids dispersed at the same time or in succession depending on the composition of the film 170. The film 170 may be self-curing or may be cured by form of stimulus, such as heating or electromagnetic radiation.

Another exemplary method for forming the pin stabilization layer may be understood by referring now to FIG. 8, which is a sectional view like FIG. 6. In this embodiment, a pin stabilization layer 170′ may be applied to the substrate 105 as a continuous sheet that includes a plurality of opening 465a, 465b and 465c. The openings 465a, 465b and 465c are spaced to match up with the pins 115 and their corresponding solder cones 225, 230 and 235. If desired, the openings 465a, 465b and 465c may have profiles that match the conic profile or other profile of the solder cones 225, 230 and 235. The sheet 170′ may be composed of the same types of materials used to compose the sheet 170 and may be self adhesive or secured to the substrate by way of an adhesive not shown.

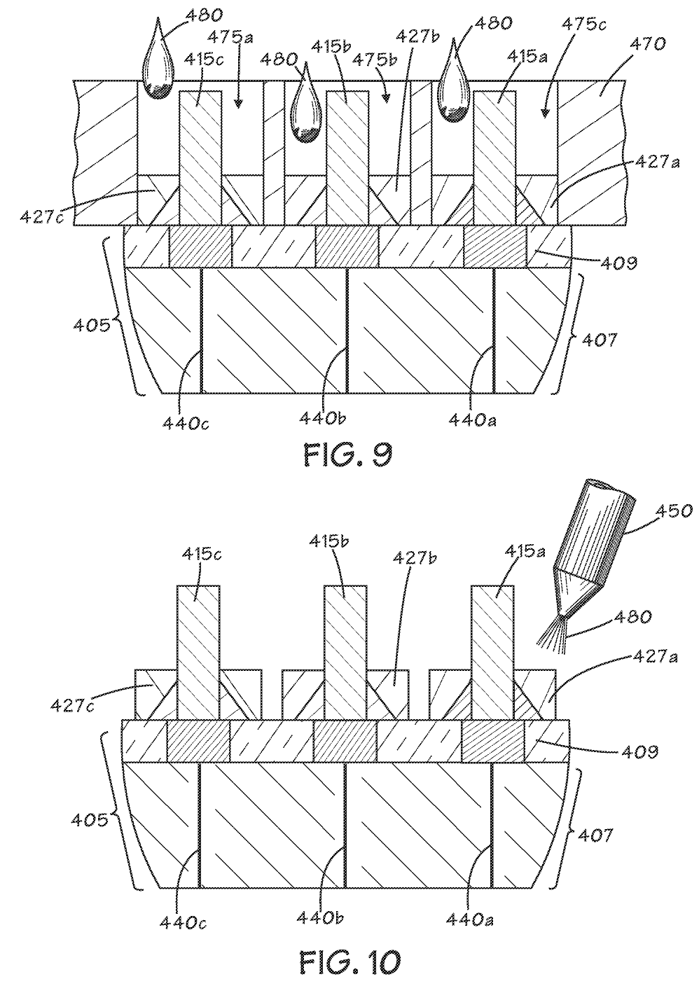

An exemplary process for forming the individual pin stabilization layers depicted in FIG. 6 may be understood by referring now to FIG. 9, which is a sectional view like FIG. 6, but with the substrate 405 flipped over and a print screen 470 seated thereon. Again, for simplicity of illustration, the substrate 405 is depicted with a simplified interconnect layer 407, an interconnect layer 409 and wires 440a, 440b and 440c that schematically represent metallization layers. The print screen 470 includes a plurality of openings 475a, 475b and 475c that are sized and spaced to correspond to the locations of the pins 415a, 415b and 415c. The openings 475a, 475b and 475c should have large enough diameters to provide for the screen printing of the individual stabilization layers 427a, 427b and 427c by way of the deposition of a liquid material 480.

An alternate exemplary method for forming the individual pin stabilization layers 427a, 427b and 427c may be understood by referring now to FIG. 10, which is a sectional view like FIG. 8. Again for simplicity of illustration, the substrate 405 is depicted with a simplified interconnect layer 407, an interconnect layer 409 and wires 440a, 440b and 440c that schematically represent metallization layers. In this embodiment, a nozzle 450 may be used to individually deposit the pin stabilization layers 427a, 427b and 427c by way of a spray 480. This may be possible where the nozzle may be accurately positioned relative to a given pin 415a, 415b and/or 415c.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
coupling first ends of plural conductor pins to a first surface of a semiconductor chip package substrate; and
forming a layer on the first surface that engages and resists lateral movement of the conductor pins while leaving second ends of the conductor pins exposed.

2. The method of claim 1, wherein the coupling of the first ends comprises soldering the first ends of the conductors pins to the semiconductor chip package substrate.

3. The method of claim 1, wherein the forming of the layer comprises depositing a liquid on the first surface and curing the liquid into a solid.

4. The method of claim 3, wherein the liquid is self-curing.

5. The method of claim 3, wherein the curing comprises stimulating the liquid with heat or electromagnetic radiation.

6. The method of claim 3, wherein the liquid is deposited by spraying.

7. The method of claim 1, wherein the layer comprises a polymeric material.

8. The method of claim 1, comprising coupling a semiconductor chip to the second surface of the semiconductor chip package substrate.

9. The method of claim 8, wherein the coupling of the semiconductor chip comprises coupling a microprocessor.

10. The method of claim 1, wherein the forming a layer comprises applying sheet to the first surface of the semiconductor chip package substrate.

11. The method of claim 10, comprising securing the sheet to the first surface with an adhesive.

12. A method of manufacturing, comprising:
coupling first ends of plural conductor pins to a first surface of a semiconductor chip package substrate; and
forming plural reinforcement layers on the first surface, each of the reinforcement layers engaging a corresponding conductor pin to resist lateral movement of that corresponding conductor pin while leaving a second end of that corresponding conductor pin exposed.

13. The method of claim 12, wherein the coupling of the first ends comprises soldering the first ends of the conductors pins to the semiconductor chip package substrate.

14. The method of claim 12 wherein the forming of the plural reinforcement layers comprises depositing a liquid on the first surface and curing the liquid into a solid.

15. The method of claim 14, wherein the liquid is self-curing.

16. The method of claim 14, wherein the curing comprises stimulating the liquid with heat or electromagnetic radiation.

17. The method of claim 14, wherein the liquid is deposited by spraying.

18. The method of claim 12, wherein the layer comprises a polymeric material.

19. The method of claim 12, comprising coupling a semiconductor chip to the second surface of the semiconductor chip package substrate.

20. The method of claim 19, wherein the coupling of the semiconductor chip comprises coupling a microprocessor.

21. An apparatus, comprising:
a substrate having a first surface including a plurality of conductor pins coupled thereto and a second surface adapted to receive a semiconductor chip; and
a layer coupled to the first surface that engages and resists lateral movement of the conductor pins while leaving second ends of the conductor pins exposed.

22. The apparatus of claim 21, wherein the plurality of conductor pins are coupled to the first surface of the substrate by solder.

23. The apparatus of claim 21, wherein the layer comprises a polymeric material.

24. The apparatus of claim 21, wherein the substrate comprises a plurality of stacked layers.

25. The apparatus of claim 21, comprising a semiconductor chip coupled to the second surface of the substrate.

26. The apparatus of claim 25, comprising a lid coupled to the second surface of the substrate.

27. The apparatus of claim 25, wherein the semiconductor chip comprises a microprocessor.

28. The apparatus of claim 21, wherein the layer comprises a sheet.

29. An apparatus, comprising:
a substrate having a first surface including a plurality of conductor pins coupled thereto and a second surface adapted to receive a semiconductor chip; and
plural reinforcement layers coupled to the first surface, each of the reinforcement layers engaging a corresponding conductor pin to resist lateral movement of that corresponding conductor pin while leaving a second end of that corresponding conductor pin exposed.

30. The apparatus of claim 29, wherein the plurality of conductor pins are coupled to the first surface of the substrate by solder.

31. The apparatus of claim 29, wherein the reinforcement layers comprise a polymeric material.

32. The apparatus of claim 29, wherein the substrate comprises a plurality of stacked layers.

33. The apparatus of claim 29, comprising a semiconductor chip coupled to the second surface of the substrate.

34. The apparatus of claim 33, comprising a lid coupled to the second surface of the substrate.

35. The apparatus of claim 33, wherein the semiconductor chip comprises a microprocessor.
